(19) United States
(12) Patent Application Publication
(10) Pub. No.: US 2013/0252436 A1
(43) Pub. Date: Sep. 26, 2013

(54) DIELECTRIC THIN FILM, METHOD OF MANUFACTURING SAME, AND APPLICATIONS THEREOF

(71) Applicant: MITSUBISHI MATERIALS CORPORATION, Tokyo (JP)

(72) Inventors: Jun Fujii, Naka-gun (JP); Hideaki Sakurai, Naka-gun (JP); Nobuyuki Soyama, Naka-shi (JP)

(73) Assignee: MITSUBISHI MATERIALS CORPORATION, Tokyo (JP)

(21) Appl. No.: 13/899,927

(22) Filed: May 22, 2013

Related U.S. Application Data
(62) Division of application No. 12/656,230, filed on Jan. 21, 2010.

(30) Foreign Application Priority Data
Dec. 28, 2007 (JP) 2007-340930
Dec. 27, 2008 (JP) 2008-335513

(51) Int. Cl. H01L 21/02

(52) U.S. Cl. CPC H01L 21/02197
USPC 438/761

(57) ABSTRACT

A dielectric thin film and a method of manufacturing the same, wherein the manufacture of a dielectric thin film having a composition represented by Ba₁₋ₓSrₓTi_{y}O₃ (wherein 0≦x≦1 and 0.9≦y≦1.1) includes applying a precursor to the thin film to a substrate and performing drying, and subsequently performing calcination by raising the temperature of the dried thin film at a rate of not more than 30° C./minute, thereby forming a dielectric thin film having an average primary particle size of not less than 70 nm, for which no cracks with a continuous linear length of 1.5 μm or greater exist at the surface of the thin film.

### BACKGROUND OF THE INVENTION

1. Field of the Invention

The present invention relates to a dielectric thin film having a high insulation withstand voltage, which is free from long cracks that extend along the thin film surface.

2. Description of Related Art

Dielectric thin films having a composition Ba₁₋ₓSrₓTi_{y}O₃ (wherein 0≦x≦1 and 0.9≦y≦1.1) have a high dielectric constant, and are therefore attracting considerable attention as capacitors for semiconductor memory or as built-in capacitors for processing IC signals (for example, see Japanese Unexamined Patent Application, First Publication No. Hei 3-257020). Examples of known methods for forming these types of dielectric thin films include sol-gel methods, CVD methods, and sputtering methods and the like. A sol-gel method is a method in which metal salts or metal alkoxides that function as the raw materials for Ba, Sr and Ti are mixed together in an organic solvent to generate a coating liquid, and this coating liquid is then applied to a substrate and crystallized.

When preparing a dielectric thin film with the composition mentioned above, the metal salts and/or metal alkoxides exhibit a high degree of solubility within the organic solvent, and therefore following application of the coating liquid, drying is usually conducted at a temperature of room temperature to 150° C., and a pre-calcination is then performed either for one hour at 500 to 600° C. or for one minute at a high temperature of 750° C. or higher. A method in which these application, drying and pre-calcination operations are repeated to increase the thickness of the film, and a final calcination is then performed at a temperature of 650° C. or higher to crystallize the film is already known (see Japanese Unexamined Patent Application, First Publication No. Hei 8-7649).

However, in a conventional thin film formation method, the high-temperature pre-calcination of 500 to 600° C. is repeated each time another coating of the coating liquid is applied, and the calcination temperature used for achieving crystallization is also very high, meaning a problem arises in that existing elements may deteriorate and unwanted oxides may be generated, resulting in a change in the properties of the produced film. Accordingly, a composition for forming a thin film has been proposed that has a composition represented by Ba₁₋ₓSrₓTi_{y}O₃ (wherein x and y are as defined above), which is prepared using specific metal salts of organic carboxylic acids as a precursor solution, is capable of undergoing recoating using a pre-calcination that is performed at a comparatively low temperature for a short period of time, and is able to be calcined at a relatively low temperature (see Japanese Unexamined Patent Application, First Publication No. Hei 9-52713). By using this composition for forming a thin film, a dielectric thin film can be formed at a calcination of temperature of approximately 550° C.

However, in conventional methods of forming dielectric thin films, a problem arises in that long cracks that extend across the surface of the thin film can often form in the dielectric thin film following calcination, causing a dramatic reduction in the insulation withstand voltage.

### SUMMARY OF THE INVENTION

The present invention has been developed in light of the above problems observed in conventional dielectric thin films, and has an object of providing a dielectric thin film in which long cracks that extend across the surface of the dielectric thin film do not exist, namely a dielectric thin film having a high insulation withstand voltage, as well as providing a method of manufacturing such a dielectric thin film.

In order to achieve the object above, the present invention relates to a dielectric thin film having the structure described below.

A dielectric thin film having a composition represented by Ba₁₋ₓSrₓTi_{y}O₃ (wherein 0≦x≦1 and 0.9≦y≦1.1), wherein the average primary particle size of the dielectric crystal particles that form the thin film is not less than 70 nm, and no cracks with a continuous linear length of 1.5 μm or greater exist at the thin film surface.

[2] A dielectric thin film according to [1] above, wherein the composition represented by Ba₁₋ₓSrₓTi_{y}O₃ satisfies 0.1≦x≦0.5 and 0.9≦y≦1.1.

[3] A dielectric thin film according to [1] or [2] above, wherein the average primary particle size of the dielectric crystal particles is not less than 70 nm and not more than 300 nm, and no cracks with a width of not less than 5 nm and not more than 60 nm and a continuous linear length of 1.5 μm or greater exist at the thin film surface.

[4] A dielectric thin film according to any one of [1] to [3] above, having an insulation withstand voltage that yields a leakage current density of less than 10⁻⁵ A/cm² at a voltage of 5 V.

[5] A dielectric thin film according to any one of [1] to [4] above, having an insulation withstand voltage that yields a leakage current density of less than 10⁻¹ A/cm² at a voltage of 20 V.

[6] A dielectric thin film according to any one of [1] to [5] above, having a stacked structure in which a passivation thin film is provided on top of the dielectric thin film.

Furthermore, the present invention also relates to a method of manufacturing the dielectric thin film and applications of the dielectric thin film described below.

[7] A method of manufacturing a dielectric thin film having a composition represented by Ba₁₋ₓSrₓTi_{y}O₃ (wherein 0≦x≦1 and 0.9≦y≦1.1), the method including applying a precursor to the thin film to a substrate and performing drying, and subsequently performing calcination by raising the temperature of the dried thin film at a rate of not more than 30° C./minute, thus forming dielectric crystal particles having an average primary particle size of not less than 70 nm, for which no cracks with a continuous linear length of 1.5 μm or greater exist at the thin film surface.

[8] A method of manufacturing a dielectric thin film according to [7] above, wherein the composition represented by Ba₁₋ₓSrₓTi_{y}O₃ satisfies 0.1≦x≦0.5 and 0.9≦y≦1.1.

[9] A method of manufacturing a dielectric thin film according to [7] or [8] above, wherein the calcination temperature is not less than 450° C. and not more than 800° C.

[10] A composite electronic component such as a thin-film capacitor, a capacitor, IPD (Integrated Passive Device), DRAM memory capacitor, stacked capacitor, transistor gate insulator, non-volatile memory, pyroelectric infrared detection device, piezoelectric element, electrooptic element, actuator, resonator, ultrasonic motor, or LC noise filter element or the like that includes a dielectric thin film according to any one of [1] to [6] above.

[11] A composite electronic component according to [10] above, which is a thin-film capacitor, a capacitor, IPD (Integrated Passive Device), DRAM memory capacitor, stacked capacitor, transistor gate insulator, non-volatile memory, pyroelectric infrared detection device, piezoelectric element, electrooptic element, actuator, resonator, ultrasonic motor, or LC noise filter element or the like having a dielectric thin film that is compatible with a frequency band of 100 MHz or higher.

[12] A precursor solution used in forming a dielectric thin film according to any one of [1] to [6] above, prepared by dissolving an organic barium compound, an organic strontium compound and a titanium alkoxide in an organic solvent such that the molar ratio of Ba:Sr:Ti=(1−x):x:y (wherein 0≦x≦1 and 0.9≦y≦1.1).

The dielectric thin film of the present invention has a composition represented by Ba₁₋ₓSrₓTi_{y}O₃ (wherein 0≦x≦1 and 0.9≦y≦1.1), and preferably has a composition represented by Ba₁₋ₓSrₓTi_{y}O₃ wherein 0.1≦x≦0.5 and 0.9≦y≦1.1. A dielectric thin film having such a composition has a high dielectric constant, and has an average primary particle size for the dielectric crystal particles that form the thin film of not less than 70 nm. As a result, cracks having a long continuous linear length are unlikely to form, and long cracks with a continuous linear length of 1.5 μm or greater do not exist, resulting in a higher insulation withstand voltage.

The dielectric thin film of the present invention has, for example, an insulation withstand voltage that yields a leakage current density of less than 10⁻⁵ A/cm² at a voltage of 5 V, or an insulation withstand voltage that yields a leakage current density of less than 10⁻¹ A/cm² at a voltage of 20 V, and is therefore ideal as a high insulation withstand voltage capacitor.

The dielectric thin film of the present invention can be manufactured by applying a precursor solution to a substrate, drying and/or pre-calcining the resulting coating, and then performing a calcination by raising the temperature at a rate of not more than 30° C./minute, and preferably at a rate of 5 to 20° C./minute.

Conventionally, the precursor solution is applied to the substrate, and following drying, is subjected to calcination in an RTA furnace (rapid thermal annealing furnace) or the like at a rate of temperature increase of approximately 600° C./minute. As a result, conventional dielectric thin films have small dielectric crystal particles, typically of 50 nm or smaller, and are prone to developing long continuous linear cracks. In the manufacturing method of the present invention, the calcination is conducted at an extremely slow rate of temperature increase that is approximately 1/100th to 1/30th that of the conventionally employed rate. By employing this method, a dielectric thin film can be formed that has a high insulation withstand voltage, in which continuous long cracks that extend across the surface of the dielectric thin film do not exist.

### BRIEF DESCRIPTION OF THE DRAWINGS

FIG. 1 is an electron microscope photograph illustrating the structural state of a dielectric thin film of example 1.

FIG. 2 is a graph illustrating the leakage current density relative to the applied voltage for the dielectric thin film of example 1.

FIG. 3 is an electron microscope photograph illustrating the structural state of a dielectric thin film of example 2.

FIG. 4 is a graph illustrating the leakage current density relative to the applied voltage for the dielectric thin film of example 2.

FIG. 5 is an electron microscope photograph illustrating the structural state of a dielectric thin film of example 3.

FIG. 6 is a graph illustrating the leakage current density relative to the applied voltage for the dielectric thin film of example 3.

FIG. 7 is an electron microscope photograph illustrating the structural state of a dielectric thin film of comparative example 1.

FIG. 8 is a graph illustrating the leakage current density relative to the applied voltage for the dielectric thin film of comparative example 1.

FIG. 9 is an electron microscope photograph illustrating the structural state of a dielectric thin film of comparative example 2.

FIG. 10 is a graph illustrating the leakage current density relative to the applied voltage for the dielectric thin film of comparative example 2.

### DETAILED DESCRIPTION OF THE INVENTION

A more detailed description of the present invention is presented below based on a series of embodiments.

The dielectric thin film of the present invention has a composition represented by Ba₁₋ₓSrₓTi_{y}O₃ (wherein 0≦x≦1 and 0.9≦y≦1.1), wherein the average primary particle size of the dielectric crystal particles that form the thin film is not less than 70 nm, and no cracks with a continuous linear length of 1.5 μm or greater exist at the thin film surface.

In the thin film composition represented by Ba₁₋ₓSrₓTi_{y}O₃, if the molar ratio does not satisfy the ranges 0≦x≦1 and 0.9≦y≦1.1, then the dielectric constant tends to decrease undesirably. In order to ensure that the thin film has a favorable dielectric constant, the molar ratio within Ba₁₋ₓSrₓTi_{y}O₃ preferably satisfies the ranges 0.1≦x≦0.5 and 0.9≦y≦1.1.

In the manufacture of the dielectric thin film having a composition represented by Ba₁₋ₓSrₓTi_{y}O₃ (wherein 0≦x≦1 and 0.9≦y≦1.1), a precursor solution prepared by dissolving an organic barium compound, an organic strontium compound and a titanium alkoxide in an organic solvent such that the molar ratio of Ba:Sr:Ti=(1−x):x:y (wherein 0≦x≦1 and 0.9≦y≦1.1) may be used. Examples of the organic barium compound and the organic strontium compound within the precursor solution include metal salts of carboxylic acids represented by a general formula CₙH₂ₙ₊₁COOH (wherein 3≦n≦7), and the use of carboxylate salts that can adopt a structure represented by general formula [I] shown below (wherein R1 to R6 each represents a hydrogen atom, a methyl group or an ethyl group, and M represents Ba or Sr) is preferred.

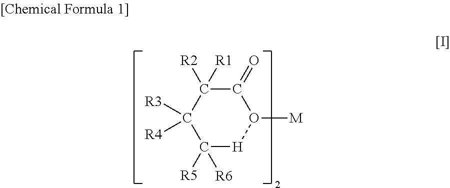

The steps of applying the above precursor solution to a substrate using a coating method such as spin coating, dip coating or spray coating, and subsequently drying the applied coating are repeated a plurality of times until the desired film thickness is obtained, and a calcination is then performed. The drying may be performed at a low temperature of 150 to 400° C. The precursor solution may be applied so that the thickness of the dielectric thin film following calcination is not less than 30 nm and not more than 800 nm.

Calcination of the applied coating is preferably conducted by heating the coating to a temperature of not less than 450° C. and not more than 800° C. at a rate of temperature increase of not more than 30° C./minute. If the rate of temperature increase exceeds 30° C./minute then cracks tend to develop within the thin film. In a preferred calcination, the coating is heated to a temperature of not less than 500° C. and not more than 750° C. at a rate of temperature increase of 5 to 20° C./minute. If the calcination temperature is less than 450° C., then the calcination tends to be inadequate, whereas cracking is more likely to occur if the temperature exceeds 800° C.

By performing the calcination treatment described above, a dielectric thin film can be obtained in which the average primary particle size of the dielectric crystal particles is not less than 70 nm, and in which no cracks with a continuous linear length of 1.5 μm or greater exist at the thin film surface. In a preferred configuration, a dielectric thin film can be formed in which the average primary particle size of the dielectric crystal particles is not less than 70 nm and not more than 300 nm, and in which no cracks with a width of not less than 5 nm and not more than 60 nm and a continuous linear length of 1.5 μm or greater exist at the thin film surface. A linear crack refers to a continuous crack in which the meander width along the lengthwise direction is not more than 400 nm. The width mentioned above refers to this meander width.

The average primary particle size of the dielectric crystal particles refers to the particle diameter in the case of spherical particles, or in the case of non-spherical particles, refers to the particle size calculated by (major axis+minor axis)/2, wherein the major axis is the longest distance across a particle, and the minor axis is the longest distance across the particle in a direction perpendicular to the major axis. Specifically, measurement of the particle size may be conducted by measuring the particles within an image such as a photograph.

In a dielectric thin film formed using the above manufacturing method of the present invention, no cracks with a continuous linear length of 1.5 μm or greater exist at the thin film surface. As a result, the dielectric thin film has a high insulation withstand voltage, which yields a leakage current density of less than 10⁻⁵ A/cm² at a voltage of 5 V, and/or a leakage current density of less than 10⁻¹ A/cm² at a voltage of 20 V.

The dielectric thin film of the present invention may have a stacked structure in which a protective film such as a passivation film is provided on top of the dielectric thin film. There are no particular restrictions on the composition of the passivation thin film or the like, and typical protective film compositions (such as PZT, PMN, PMN-PT, polyimide, Si₃N₄, SiON, PSG (Phospho-Silicate-Glass) films, BPSG (Boro-Phospho-Silicate-Glass) films, or BCB (benzocylobutene) organic films) may be used.

The dielectric thin film of the present invention may be widely used in composite electronic components such as thin-film capacitors, capacitors, IPD (Integrated Passive Devices), DRAM memory capacitors, stacked capacitors, transistor gate insulators, non-volatile memory, pyroelectric infrared detection devices, piezoelectric elements, electrooptic elements, actuators, resonators, ultrasonic motors, and LC noise filter elements and the like.

Furthermore, the dielectric thin film of the present invention may also be widely used in composite electronic components such as thin-film capacitors, capacitors, IPD (Integrated Passive Devices), DRAM memory capacitors, stacked capacitors, transistor gate insulators, non-volatile memory, pyroelectric infrared detection devices, piezoelectric elements, electrooptic elements, actuators, resonators, ultrasonic motors and LC noise filter elements having a dielectric thin film that is compatible with a frequency band of 100 MHz or higher.

### EXAMPLES

Examples of the present invention are presented below, together with a series of comparative examples. In each of the examples, the thickness of the thin film is 350 nm. Descriptions of the methods used for measuring the average primary particle size and the size of cracks, the measurement conditions employed for the scanning electron microscope (SEM), and the method used for measuring the leakage current density are presented below. The results of the measurements are listed in Table 1.

### [Average Primary Particle Size]

The average primary particle size of the dielectric crystals was determined by selecting 100 random crystal particles that appear within the scanning electron microscope photograph, measuring the particle size of each crystal with calipers, and then calculating the average of the measured primary particle sizes.

### [Size of Cracks]

The cracks that were apparent between dielectric crystals in the scanning electron microscope photograph were measured using calipers.

### [Scanning Electron Microscope (SEM)]

Measurements were conducted using a FE-SEM (Hitachi S-900, resolution: 0.7 nm) at an accelerating voltage of 5 kV and a magnification of 50,000×.

### [Leakage Current Density]

The leakage current density was measured using a leakage current density meter (Keithley 236 SMU), under conditions including a bias step of 0.5 V, a delay time of 0.1 seconds, a temperature of 23° C., and a humidity of 50±10%.

### Example 1

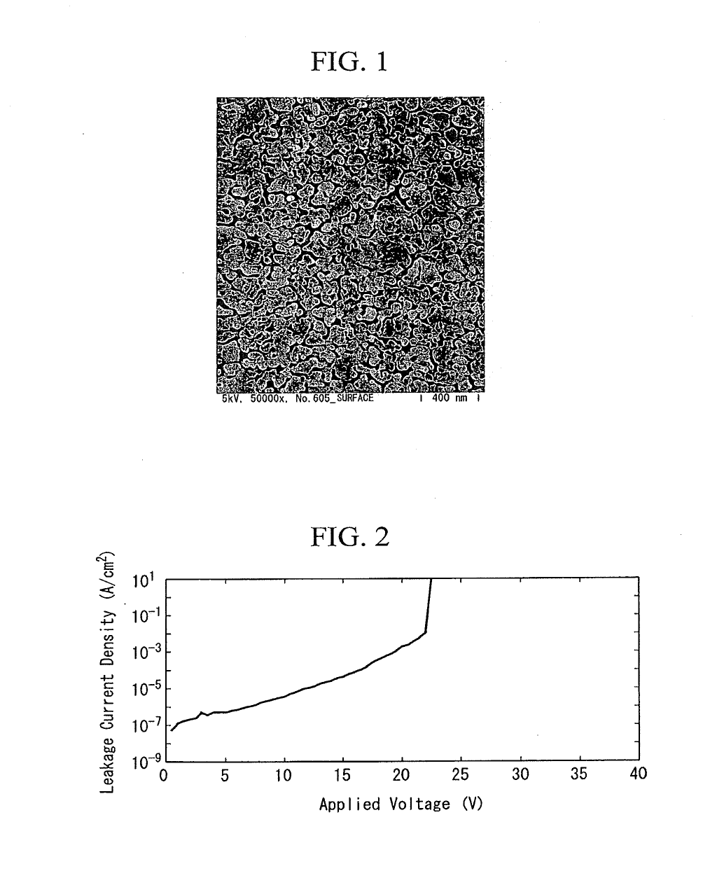

A coating was formed using a precursor solution prepared so that the molar ratio of Ba/Sr/Ti was 70/30/100, and the coating was then dried at 350° C. for 5 minutes, subsequently heated to 700° C. at a rate of temperature increase of 5° C./minute, and then calcined at 700° C. for 60 minutes. An SEM image of the resulting thin film and the thin film leakage properties are illustrated in FIG. 1 and FIG. 2 respectively.

### Example 2

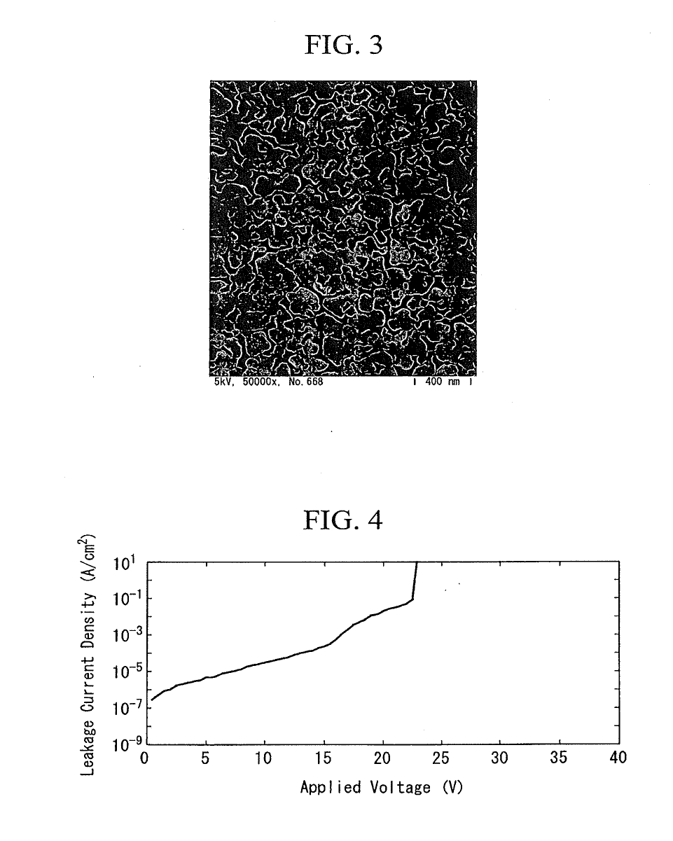

A coating was formed using a precursor solution prepared so that the molar ratio of Ba/Sr/Ti was 70/30/100, and the coating was then dried at 350° C. for 5 minutes, subsequently heated to 800° C. at a rate of temperature increase of 5° C./minute, and then calcined at 800° C. for 60 minutes. An SEM image of the resulting thin film and the thin film leakage properties are illustrated in FIG. 3 and FIG. 4 respectively.

### Example 3

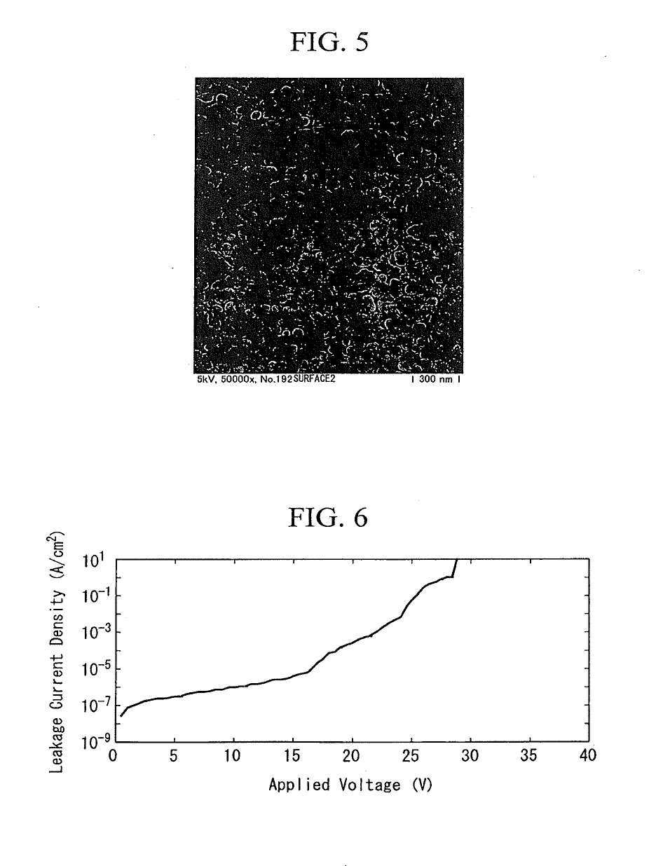

A coating was formed using a precursor solution prepared so that the molar ratio of Ba/Sr/Ti was 70/30/100, and the coating was then dried at 350° C. for 5 minutes, subsequently heated to 700° C. at a rate of temperature increase of 20° C./minute, and then calcined at 700° C. for 60 minutes. An SEM image of the resulting thin film and the thin film leakage properties are illustrated in FIG. 5 and FIG. 6 respectively.

### Comparative Example 1

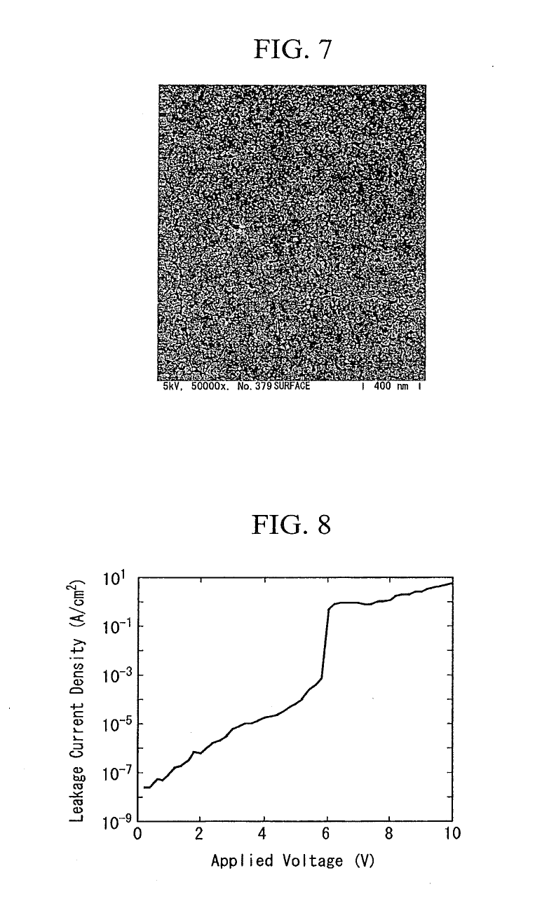

A coating was formed using a precursor solution prepared so that the molar ratio of Ba/Sr/Ti was 70/30/100, and the coating was then dried at 350° C. for 5 minutes, subsequently heated to 700° C. at a rate of temperature increase of 600° C./minute, and then calcined at 700° C. for 5 minutes. An SEM image of the resulting thin film and the thin film leakage properties are illustrated in FIG. 7 and FIG. 8 respectively.

### Comparative Example 2

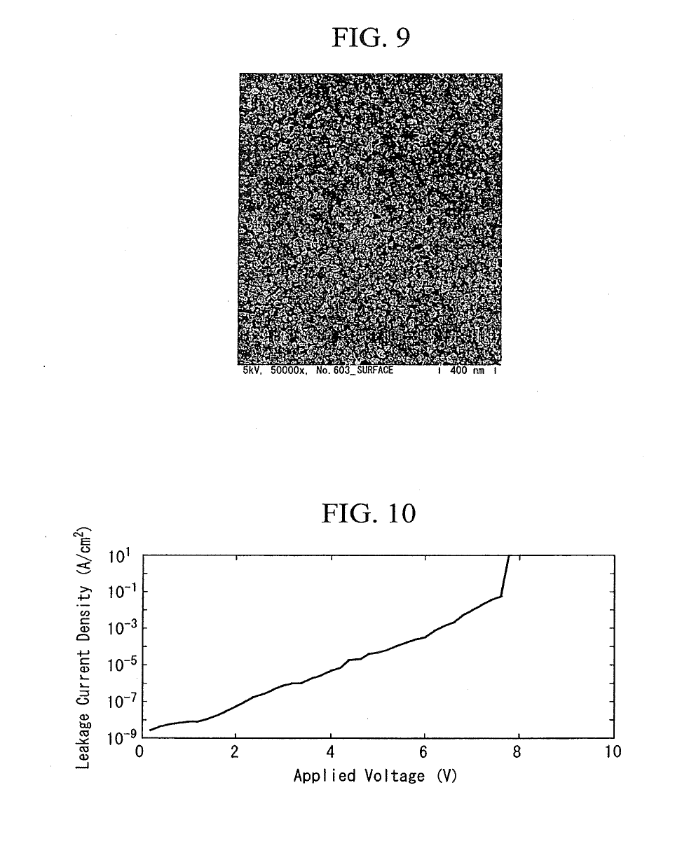

A coating was formed using a precursor solution prepared so that the molar ratio of Ba/Sr/Ti was 70/30/100, and the coating was then dried at 350° C. for 5 minutes, subsequently heated to 800° C. at a rate of temperature increase of 600° C./minute, and then calcined at 800° C. for 5 minutes. An SEM image of the resulting thin film and the thin film leakage properties are illustrated in FIG. 9 and FIG. 10 respectively.

As illustrated in FIG. 7, in the dielectric thin film of comparative example 1, three large cracks existed at the thin film surface. In the figure, the crack that extends in a vertical direction and the upper crack that extends horizontally had a meander width along the lengthwise direction of not more than 100 nm and a crack length that exceeded 1.5 μm (1,500 nm). The lower crack that extends horizontally in the figure had a meander width along the lengthwise direction of not more than 300 nm and a crack length that exceeded 1.5 μm. As illustrated in FIG. 9, a large Y-shaped crack existed in the dielectric thin film of comparative example 2, the upper portion of the crack had a meander width of not more than 300 nm, and the crack length exceeded 1.5 μm.

In this manner, because large cracks existed in the thin films of comparative example 1 and 2, when the applied voltage exceeded 6 to 8 V, the leakage current density increased rapidly to a value of 10⁻¹ A/cm² or greater.

In contrast, as is evident from FIG. 1, FIG. 3 and FIG. 5, the dielectric thin films of examples 1 to 3 each had an average primary particle size for the dielectric crystal particles of not less than 70 nm, and specifically, had an average primary particle size within a range from approximately not less than 70 nm to not more than 300 nm, and no cracks with a continuous linear length of 1.5 μm or greater existed in the thin film. As a result, as illustrated in FIG. 2, FIG. 4 and FIG. 6, the dielectric thin films of examples 1 to 3 each had a high insulation withstand voltage, with a leakage current density of less than 10⁻¹ A/cm² at a voltage of 20 V.

TABLE 1

| | | | | Calcination | Average | | | | |
|---|---|---|---|---|---|---|---|---|---|
| | Composition | | | Rate of | primary | Cracks | | Leakage current | |
| | molar ratio | | | temperature | particle | | Meander | density | |
| | Ba | Sr | Ti | increase | size | Length | width | 5 V | 20 V |
| Example 1 | 70 | 30 | 100 | 5° C./minute | 130 | 0.35 | 30 | <10⁻⁶ | <10⁻² |
| Example 2 | 70 | 30 | 100 | 5° C./minute | 130 | 0.42 | 50 | <10⁻⁵ | <10⁻¹ |
| Example 3 | 70 | 30 | 100 | 20° C./minute | 120 | 0.25 | 30 | <10⁻⁶ | <10⁻³ |
| Comparative example 1 | 70 | 30 | 100 | 600° C./minute | 30 | 1.8 | 300 | 10⁻⁴ | — |
| Comparative example 2 | 70 | 30 | 100 | 600° C./minute | 40 | 2.4 | 300 | 10⁻⁵ to 10⁻⁴ | — |

(Notes)
The average primary particle size units are nm, the crack length units are μm, the crack meander width units are nm, and the leakage current density units are [A/cm²]. The 5 V and 20 V results represent the leakage current densities at 5 V and 20 V respectively.

While preferred embodiments of the invention have been described and illustrated above, it should be understood that these are exemplary of the invention and are not to be considered as limiting. Additions, omissions, substitutions, and other modifications can be made without departing from the scope of the present invention. Accordingly, the invention is not to be considered as being limited by the foregoing description, and is only limited by the scope of the appended claims.

1-12. (canceled)

13. A method for manufacturing a dielectric thin film having a composition represented by Ba₁₋ₓSrₓTi_{y}O₃ (wherein 0.1≦x≦0.5 and 0.9≦y≦1.1), comprising the steps of:
preparing a precursor solution by dissolving an organic barium compound, an organic strontium compound, and a titanium alkoxide dissolved in an organic solvent such that a molar ratio of Ba:Sr:Ti is (1−x):x:y (wherein 0.1≦x≦0.5 and 0.9≦y≦1.1), and the organic barium compound and the organic strontium compound being metal salts of carboxylic acids represented by a formula CₙH₂ₙ₊₁COOH (3≦n≦7);
applying the precursor solution to a substrate to form a coating and drying the coating at a temperature of 150° C. to 400° C.;
repeating the step of applying and drying to form a dried coating; and
performing calcination treatment by heating the dried coating to a temperature of not less than 450° C. and not more than 800° C. at a rate of temperature increase of 5 to 20° C./minute to form the dielectric thin film, which is formed by dielectric crystal particles having an average primary particle size of not less than 70 nm and not more than 300 nm, and
the dielectric thin film having no cracks which have a width of not less than 5 nm and not more than 60 nm and a continuous linear length of 1.5 μm or greater at a surface of the dielectric thin film, and the dielectric thin film having a thickness of not less than 30 nm and not more than 800 nm and a leakage current density of less than 10⁻¹ A/cm² at a voltage of 20V.

14. A method for manufacturing a dielectric thin film according to claim 13, further comprising the steps of providing a passivation film on a top of the dielectric thin film.
